(19) United States
(12) Patent Application Publication
(10) Pub. No.: US 2022/0206401 A1
(43) Pub. Date: Jun. 30, 2022

(54) MIRROR ASSEMBLY HAVING A HYDROGEN BARRIER AND OPTICAL ASSEMBLY

(71) Applicant: Carl Zeiss SMT GmbH, Oberkochen (DE)

(72) Inventors: Alexandra PAZIDIS, Essingen-Lautenburg (DE); Kerstin HILD, Waldstetten (DE); Thilo POLLAK, Neresheim (DE); Martin NOAH, Oberkochen (DE); Juergen NASER, Diebach (DE); Dirk KLEINHENZ, Aalen (DE)

(21) Appl. No.: 17/685,432

(22) Filed: Mar. 3, 2022

Related U.S. Application Data
(63) Continuation of application No. PCT/EP2020/070103, filed on Jul. 16, 2020.

(30) Foreign Application Priority Data
Sep. 3, 2019 (DE) 10 2019 213 349.5

(51) Int. Cl. G03F 7/20; G02B 26/08; G02B 7/185

(52) U.S. Cl. CPC G03F 7/70983; G02B 26/0816; G02B 5/0808; G02B 7/185; G03F 7/70266

(57) ABSTRACT

A mirror arrangement (30) includes: a substrate (31), which has a front side (31a) having a mirror face (32a) for reflecting radiation (5), and a rear side (31b) facing away from the front side (31a), as well as at least one actuator (27) arranged to generate deformations of the mirror face (32a). The at least one actuator (27) is secured on the rear side (31b) of the substrate (31), and the mirror arrangement (30) has a hydrogen barrier (38) which is configured to protect a hydrogen-sensitive material (M) on the rear side (31b) of the substrate (31), in particular on the at least one actuator (27), from the attack by hydrogen (37) from the surroundings (36) of the mirror arrangement (30). An associated optical arrangement, in particular an EUV lithography apparatus (1), incorporating such a mirror arrangement (30) is also disclosed.

### CROSS-REFERENCE TO RELATED APPLICATION

This is a Continuation of International Application PCT/EP2020/070103, which has an international filing date of Jul. 16, 2020, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2019 213 349.5 filed on Sep. 3, 2019.

### FIELD OF THE INVENTION

The invention relates to a mirror arrangement comprising: a substrate, which comprises a front side having a mirror face for reflecting radiation and a rear side facing away from the front side, as well as an actuator or a plurality of actuators, in the form of an actuator assembly, for example, for generating deformations of the mirror face. The invention also relates to an optical arrangement, in particular an EUV lithography apparatus, having at least one such mirror arrangement.

### BACKGROUND

The mirror arrangement described above enables targeted (local) deformation, with the actuators, of the mirror face formed on the front side of the substrate. The purpose of deforming the mirror face may be, for example, to carry out targeted correction of aberrations of an EUV lithography apparatus in which the mirror arrangement is disposed.

U.S. Pat. No. 5,986,795 describes a deformable mirror for EUV radiation wherein actuators are disposed between a front plate, which forms the rear side of the mirror, and a reaction plate and are coupled to both plates, so as to bring about deformations on the mirror face of the deformable mirror.

In an optical arrangement such as an (EUV) lithography unit, for example, it may be necessary to admix hydrogen to the surroundings of the mirror arrangement permanently or, for example, during cleaning cycles. The hydrogen in this case may be present in all excitation states: As a molecule (H₂), in atomic form, in the form of excited molecules or atoms, or in the form of hydrogen ions. The presence of the hydrogen in different excitation states is promoted by the presence of EUV radiation. Numerous materials suffer under the attack of hydrogen, and accordingly are hydrogen-sensitive materials. It is therefore necessary either to select materials which are stable to the attack of hydrogen, or to protect hydrogen-sensitive materials from the attack of hydrogen.

### SUMMARY

It is an object of the invention to provide a mirror arrangement and also an optical arrangement having at least one such mirror arrangement, wherein hydrogen-sensitive materials are protected efficiently from the attack of hydrogen.

According to one formulation, this object is achieved with a mirror arrangement of the aforementioned type wherein the at least one actuator is secured on the rear side of the substrate and wherein the mirror arrangement comprises a hydrogen barrier which is configured to protect hydrogen-sensitive material on the rear side of the substrate, in particular on the at least one actuator, from the attack by hydrogen from the surroundings of the mirror arrangement.

The invention proposes that the actuator/actuators be secured on the rear side of the substrate and that they—and also any further hydrogen-sensitive materials present on the rear side of the substrate—be protected by a hydrogen barrier from hydrogen in the surroundings of the mirror arrangement. The hydrogen-sensitive material may be, for example, the actuator itself or an actuator housing, insulator layers, conductor cables/conductor tracks, etc., mounted on the rear side of the substrate. If the substrate is exposed on the rear side and if the substrate is a hydrogen-sensitive material, the substrate itself may also be protected via the hydrogen barrier from the attack of hydrogen.

The actuators may be secured in a regular arrangement or in a grid (actuator array) on the rear side of the substrate, though in principle any desired arrangement of the actuators on the rear side of the substrate is possible. Generally speaking, adjacent actuators or adjacent groups of interconnected actuators (actuator assemblies) do not directly border one another in places on the rear side of the substrate, but are instead spaced apart from one another; in other words, there is an interspace or a gap formed between pairs of adjacent actuators or actuator assemblies.

In one embodiment the at least one actuator is secured with an adhesive layer on the rear side of the substrate, with exposed surface regions of the adhesive layer being protected at least partly, in particular completely, by the hydrogen barrier from the attack of hydrogen. In this case the actuators are adhered on the substrate either directly or indirectly, i.e., by way of one or more interlayer(s), on the rear side of the substrate. As a rule, a continuous adhesive layer is used for the securement of the actuators, meaning that the adhesive layer also extends into the interspaces between adjacent actuators and/or between multiple groups of interconnected actuators.

The surface regions of the adhesive layer that are exposed to the surroundings may be formed, for example, in the interspaces between the actuators. In the region of the interspaces, the adhesive layer may be thicker than in the region between the respective actuators and the rear side of the substrate, though it is also possible for the adhesive layer to be applied thinly enough that it is not thicker, in the interspaces or gaps between the actuators, than the adhesive layer in the region in which the actuators are connected to the substrate or to the interlayer.

In one development the hydrogen barrier forms a water vapor diffusion barrier for protecting the adhesive layer from water vapor. In this case the hydrogen barrier additionally fulfills the function of a water vapor diffusion barrier for additionally protecting the adhesive layer from penetration by moisture. Owing to the smaller molecular size of hydrogen in comparison with water vapor, the requirements imposed on a material which forms a hydrogen barrier are generally more stringent than for a water vapor diffusion barrier. Materials which are suitable as a hydrogen barrier are therefore generally also suitable as a water vapor diffusion barrier, but, as a rule, the opposite is not the case.

The penetration of moisture or a change in the moistness in the surroundings of the mirror arrangement is a problem in particular for the adhesive layer or for other organic materials connected mechanically to the mirror, since in the event that the adhesive layer absorbs moisture from the surroundings, the adhesive layer or the organic material expands and in that case stresses may be introduced into the adhesive layer or the organic material. The stresses in the adhesive layer or the organic material are generally transmitted to the substrate, and so the substrate as well is subject to stresses, and this results in a drift, i.e., an (unwanted) alteration over time, of the deformations generated on the mirror face. Because of the change in moisture, therefore, there are aberrations in the beam path of the optical arrangement. Moisture penetrates the adhesive layer or the organic material in particular at the exposed regions of adhesive or regions of the organic material, and it is consequently advantageous if the hydrogen barrier serves, at least in the exposed regions, as a water vapor diffusion barrier. It will be appreciated that the hydrogen barrier may form a water diffusion barrier not only in these exposed surface regions but also in the region in which the actuators are applied to the rear side of the substrate.

In another development a surface of the hydrogen barrier that faces the surroundings is hydrophobic and/or the hydrogen barrier comprises at least one hydrophobic material. If the surface of the hydrogen barrier that faces the surroundings is hydrophobic, the uptake of moisture can be reduced. The material on the top side of the hydrogen barrier may be rendered hydrophobic, for example, by a surface treatment, e.g., by a plasma treatment, and/or by (optionally pulsed) irradiation with UV radiation, by a coating or by a surface termination. The hydrogen barrier itself may also comprise at least one hydrophobic material in order to counteract the penetration of water vapor and so form a water vapor diffusion barrier.

In another embodiment the hydrogen barrier has a hydrogen diffusion coefficient of less than 5×10⁻¹⁴ m²/s, preferably of less than 1×10⁻¹⁷ m²/s, more preferably of less than 1×10⁻²¹ m²/s. In order to ensure a maximum protective effect of the hydrogen barrier for the hydrogen-sensitive materials, as little hydrogen as possible ought to be able to pass through the hydrogen barrier. In order to achieve this, the hydrogen barrier is constructed of layers, materials and/or material combinations which have a hydrogen diffusion coefficient lower than the values indicated above. The hydrogen diffusion coefficient is indicated below illustratively for a number of materials: Ru: 4×10⁻¹⁴ m²/s, Al: 1×10⁻¹⁴ m²/s, Al₂O₃: 10⁻²³ m²/s (amorphous) or 10⁻²⁸ m²/s (crystalline). The hydrogen diffusion coefficient is based here, as is generally customary, on standard conditions (1 atm, 25° C.).

In another embodiment the hydrogen barrier comprises at least one material and/or a material combination having a lower solubility for hydrogen than the hydrogen-sensitive material. The solubility is defined for hydrogen under atmospheric pressure and refers to the volume of (molecular) hydrogen (in cubic centimeters) which is absorbed by 100 grams of the material absorbing the hydrogen. For details of this definition, reference is made to the article cited in US 2016/0187543 A1, “A Theoretical Formula for the Solubility of Hydrogen in Metals” by R. H. Fowler et al., Proc. R. Soc. Lond. A 160, page 37ff. (1937), which is incorporated by reference in its entirety in the content of this application. As a result of the lower solubility for hydrogen, it is possible to counteract embrittlement of the material of the hydrogen barrier. In this way it is possible to extend the service life of the mirror arrangement, or of its hydrogen-sensitive materials and/or components, meaning that they need be replaced less frequently. It is advantageous, moreover, if materials or material combinations selected for the hydrogen barrier are such that they do not form any gaseous hydrogen compounds.

In one embodiment the hydrogen barrier comprises at least one material in the form of an oxygen-containing chemical compound having a free enthalpy of formation (Gibbs energy) under standard conditions, based on 1 mol of oxygen, of less than −400 kJ/mol O₂, preferably of less than −800 kJ/mol O₂, more preferably of less than −1000 kJ/mol O₂.

In another embodiment the hydrogen barrier comprises at least one material in the form of a nitrogen-containing chemical compound having a free enthalpy of formation (Gibbs energy) under standard conditions, based on 1 mol of nitrogen, of less than −200 kJ/mol N₂, preferably of less than −350 kJ/mol N₂, more preferably of less than −600 kJ/mol N₂.

Chemical compounds in particular which have a high free enthalpy of formation are in general chemically inert to the attack of hydrogen and therefore highly suitable as materials for a hydrogen barrier. In selecting the material it is also possible to compare the free enthalpy of formation of a respective oxide or nitride compound with an associated hydride generated by chemical reaction of the respective material-metallic material, for example—with hydrogen. The free enthalpy of formation of the respective compound (or the amount of the enthalpy of formation) ought to be greater than that of the respective hydride compound. The free enthalpy of formation, G, takes account of the fact that the reaction with hydrogen produces gaseous reaction products, whereas the enthalpy of formation H, used in WO 2013/124224 A1 as a criterion for the selection of materials for a protective layer system, does not take account of this fact. In the context of the formation of gaseous reaction products, the enthalpy of formation H of a material may be low, but because of the increase in entropy a reaction with hydrogen may nevertheless take place.

In one embodiment the hydrogen barrier comprises at least one metal oxide which is preferably selected from the group comprising: Al₂O₃, MgO, CaO, La₂O₃, TiO₂, ZrO₂, Ta₂O₅, Al₂O₃, Y₂O₃, Ce₂O₃, and compounds thereof. Al₂O₃ has a free enthalpy of formation (Gibbs energy), based on 1 mol of oxygen under standard conditions, of around −1050 kJ/mol O₂. The other metal oxides stated also have a high free enthalpy of formation and are therefore very largely chemically inert to the attack of hydrogen.

In another embodiment the hydrogen barrier comprises at least one material which is selected from the group comprising: Al, Au, Ag, Zn, Mo, Si, W, Ti, Sn, Sb, Pt, Ni, Fe, Co, Cr, V, Cu, Mn, Pb, their oxides, borides, nitrides and carbides, and also C and B₄C, and compounds of the stated materials. Some of these materials are identified in DE 10 2017 200 667 A1, for example, as materials for a braking layer system intended to counteract penetration by hydrogen atoms through to a mirror substrate. The selection of materials is dependent on the crystal structure: for example, a close-packing is advantageous, as exists in the case of Al, Au, Ag, Zn. Certain of the materials, examples being Mo, Si, C and B₄C, are frequently used in EUV lithography units.

In another embodiment the hydrogen barrier forms a coating which covers the hydrogen-sensitive material at least partly, in particular completely. The coating may comprise a single layer or may be formed of a plurality of layers applied one over another. The coating is preferably applied directly to the hydrogen-sensitive material on the rear side of the substrate, i.e., in particular to the actuators, to the adhesive layer, to insulator layer(s), to conductor cables or conductor tracks, etc., which are formed of materials which degrade on contact with hydrogen.

The coating, or at least one layer of the coating, preferably comprises a material which has the properties described earlier on above in terms of the hydrogen diffusion coefficient and also in terms of the solubility with respect to hydrogen. The material in question may in particular be one of the materials described earlier on above. Typically at least one layer comprises or consists of a material which has a lower solubility for hydrogen than the hydrogen-sensitive material to be protected.

The materials indicated earlier above, and other materials, of the coating and of the hydrogen barrier layer may be applied through various coating methods to the rear side of the substrate and/or to the components provided there. The material may be deposited from the gas phase, for example by physical vapor deposition (PVD), in particular by plasma-enhanced PVD, by chemical vapor deposition (CVD), in particular by plasma-enhanced CVD (PECVD), by atomic layer deposition (ALD), in particular by plasma-enhanced ALD, by sputtering, in particular magnetron sputtering, etc. Sputtering and electron beam evaporation, in particular, have proven advantageous for the application of metallic layers.

It is generally advantageous, for the purpose of achieving a good barrier effect, if the material of the hydrogen barrier layer is applied in a manner such that the layer exhibits a maximum density and has as few pinholes as possible through which hydrogen can penetrate into the underlying materials.

The hydrogen barrier is preferably configured as a coating in the form of a multilayer system with barrier layers of different materials, as described in DE 10 2017 200 667 A1, for example, which in its entirety is made part of the content of this application by reference. In the case, for example, of a double layer system, i.e., of a coating comprising a pair of layers, the pinholes or defects in one individual layer are not continued as pinholes or defects in the following individual layer. In the coating, therefore, different materials from among the materials already identified earlier on above are applied preferably in alteration, i.e. as a double layer. With particular preference a plurality of double layers are applied. The materials in question may be, for example, alternately applied nitrides and carbides, in particular MAX phases, these being layered hexagonal nitrides and carbides. It will be appreciated that three or more of the above-stated materials may also be used in a coating in the form of a multilayer system.

In one development the coating comprises at least one hydrogen barrier layer which is applied on another layer. In this case the coating comprises a combination of a thick, covering layer with a hydrogen barrier layer composed of a material having a high barrier effect. The further layer, lying under the hydrogen barrier layer and covering the hydrogen-sensitive material, has the function here of compensating irregularities in the substrate and providing better growth conditions for the hydrogen barrier layer. The covering layer may comprise SiO₂, for example. The covering layer is typically more than 100 nm thick; the hydrogen barrier layer is typically thinner than 100 nm. In a coating of this kind as well, multiple double layers of covering layer and hydrogen barrier layer may be combined. It will additionally be appreciated that a double layer system or multilayer system of multiple hydrogen barrier layers may also be located on the covering layer.

In another embodiment the hydrogen barrier comprises a protective film which covers the hydrogen-sensitive material at least partly, in particular completely. The protective film is typically adhered to the hydrogen-sensitive materials. The protective film need not necessarily make contact at every place with the materials to be protected, or with their surface(s); in other words, at least in subregions, there may be an interspace formed between the protective film and the hydrogen-sensitive material. It has nevertheless proven advantageous if the protective film is applied over the full area of the rear side of the substrate or to the materials/components to be protected on the rear side of the substrate. The protective film itself may serve as a hydrogen barrier if it is formed of or comprises a material which has a low hydrogen diffusion coefficient and/or a low solubility for hydrogen, as described earlier on above. A material of this kind may optionally be formed on the surface of the protective film facing, or facing away from, the surroundings.

In another embodiment the protective film has at least one hydrogen barrier layer on its surface facing the surroundings and/or on its surface facing away from the surroundings. The hydrogen barrier layer may comprise, for example, a metallic layer, in particular an aluminum layer or an aluminum oxide layer. The hydrogen barrier layer applied to the surface of the protective film that faces the surroundings may also provide protection from the attack by hydrogen to the material of the underlying protective film, if that material is hydrogen-sensitive. The hydrogen barrier layer may also be mounted on the surface of the protective film that faces away from the surroundings, if the protective film itself is hydrogen-resistant. In this way, water can be kept away from the hydrogen barrier layer.

As described earlier on above, the adhesive layer may be applied with a nonuniform thickness, meaning that it projects only slightly, or not at all, into the interspace between the actuators. If the protective film is adhered to the top side of the actuators, the side facing away from the substrate, then the protective film may in principle extend in a planar manner, without reaching down into the interspaces between the actuators and also without coming into contact with the surface of the adhesive layer.

In one embodiment the protective film projects into a respective interspace between the side faces of the actuators and covers a preferably pot-shaped or groove-shaped depression in the adhesive layer. In general it is advantageous if the protective film projects into a respective interspace and is in contact with or connected to the adhesive layer. In the simplest case, the connection may be produced by adhering the protective film to the as yet not completely dried adhesive layer, or if the protective film itself is self-adhesive. In the case where the adhesive layer projects partly upward into the interspace between the actuators, the protective film may be connected over the full area to the adhesive layer, by being pressed in, for example, so forming a pot-shaped or groove-shaped depression in the adhesive layer. In this case the adhesive layer may optionally project at least into the interspaces upwardly over the actuators, and the entire adhesive layer may optionally have a thickness which is greater than the height of the actuators, meaning that the adhesive layer projects not only into the interspaces (except for the pot-shaped or groove-shaped depression) but also, overall, over the actuators. If the adhesive layer does not project, or projects only partly, into the interspaces, the protective film may optionally be secured, in particular glued, directly on the side faces of the actuators. The protective film is generally formed of a flexible material and may comprise a plurality of layers.

In principle, additional adhesion promoter layers or other functional layers may be applied at each interface on the rear side of the substrate, e.g. on the coating or on the protective film. For example, (further) protective layers may be applied which protect the materials on the rear side of the substrate from other contaminants (and also, optionally, additionally from hydrogen). Layers of this kind may in particular be integrated into or applied to the coating described earlier on above or the protective film.

In another embodiment the actuators are configured as piezo actuators or electrostrictive actuators. Through piezo actuators or electrostrictive actuators, i.e., actuators which comprise at least one electrostrictive material, it is possible to generate very small deformations in the substrate in a targeted way. The piezo actuators or electrostrictive actuators may, for example, be linear actuating motors which exert a substantially pointwise force effect on the substrate. It will be appreciated that in place of piezo actuators or electrostrictive actuators, other kinds of actuators may also be used. The actuators may be disposed in particular in the manner of a grid on the rear side of the substrate. Associated insulator layers, conductor cables and conductor tracks are likewise mounted on the rear side of the substrate and may be protected by the hydrogen barrier.

A further aspect of the invention relates to an optical arrangement, in particular to an EUV lithography apparatus, which comprises at least one mirror arrangement as described earlier on above. For the purposes of this application, a lithography apparatus is understood to be an (optical) apparatus which can be used in the field of lithography. Apart from a lithography unit which serves for producing semiconductor components, the apparatus may be, for example, an inspection system for the inspection of a photomask used in a lithography unit (and hereinafter also referred to as a reticle), for the inspection of a semiconductor substrate to be structured (hereinafter also referred to as a wafer), or a metrology system which is used for measuring a lithography unit or parts thereof, for measuring a projection system, for example.

The optical arrangement or the lithography apparatus may in particular be an EUV lithography apparatus which is configured for used radiation at wavelengths in the EUV wavelength range between around 5 nm and around 30 nm, or may be a DUV lithography apparatus which is configured for used radiation in the DUV wavelength range between around 30 nm and around 370 nm. The optical elements or the mirror arrangement of an EUV lithography apparatus are typically operated in a vacuum environment.

Further features and advantages of the invention are evident from the following description of exemplary embodiments of the invention, with reference to the figures of the drawing showing details essential to the invention, and from the claims. The individual features can each be realized individually by themselves or as a plurality in any desired combination in one variant of the invention.

### BRIEF DESCRIPTION OF THE DRAWINGS

Exemplary embodiments are illustrated in the schematic drawing and are explained in the following description. In the figures:

FIG. 1 shows a schematic representation of an EUV lithography unit with a mirror which comprises a plurality of actuators for correcting aberrations;

FIG. 2 shows a schematic sectional representation of a mirror arrangement with the mirror of FIG. 1 and with an adhesive layer for securing the actuators on a substrate;

FIG. 3 shows a schematic representation of a detail of the mirror arrangement of FIG. 2, in which the adhesive layer projects over the actuators and a depression is formed between the actuators, this depression being covered by a hydrogen-protective film; and

FIGS. 4A and 4B show schematic representations analogous to FIG. 3, with a coating applied to one surface of the adhesive layer and also to the actuators, said coating formed either as a single, thick hydrogen barrier layer (FIG. 4A) or as a thin hydrogen barrier layer and a further, comparatively thick covering layer (FIG. 4B).

### DETAILED DESCRIPTION

In the following description of the drawings, identical reference signs are used for identical or functionally identical components.

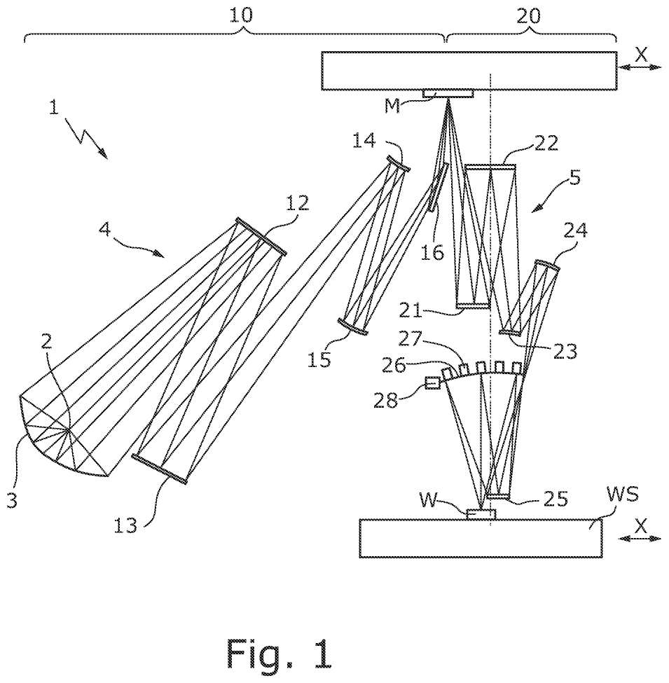

FIG. 1 schematically shows the construction of an apparatus for EUV lithography in the form of an EUV lithography unit 1, specifically of a so-called wafer scanner. The EUV lithography unit 1 comprises an EUV light source 2 for generating EUV radiation which has a high energy density in the EUV wavelength range below 50 nanometers, in particular between approximately 5 nanometers and approximately 15 nanometers. The EUV light source 2 can be configured for example in the form of a plasma light source for generating a laser-induced plasma. The EUV lithography unit 1 shown in FIG. 1 is designed for an operating wavelength of the EUV radiation of 13.5 nm. However, it is also possible for the EUV lithography unit 1 to be configured for a different operating wavelength in the EUV wavelength range, such as 6.8 nm, for example.

The EUV lithography unit 1 further comprises a collector mirror 3 in order to focus the EUV radiation of the EUV light source 2 to form a bundle illumination beam 4 and to increase the energy density further in this way. The illumination beam 4 illuminates a structured object M with an illumination system 10, which in the present example has five reflective optical elements 12 to 16 (mirrors).

The structured object M can be for example a reflective photomask, which has reflective and non-reflective, or at least less reflective, regions for producing at least one structure on the object M. Alternatively, the structured object M can be a plurality of micro-mirrors, which are arranged in a one-dimensional or multi-dimensional arrangement and which are optionally movable about at least one axis, in order to set the angle of incidence of the EUV radiation on the respective mirror.

The structured object M reflects part of the illumination beam 4 and shapes a projection beam 5, which carries the information about the structure of the structured object M and is irradiated into a projection lens 20, which generates an image of the structured object M or of a respective subregion thereof on a substrate W. The substrate W, for example a wafer, comprises a semiconductor material, for example silicon, and is disposed on a mounting, which is also referred to as a wafer stage WS.

In the present example, the projection lens 20 has six reflective optical elements 21 to 26 (mirrors) in order to generate an image of the structure that is present at the structured object M on the wafer W. The number of mirrors in a projection lens 20 typically lies between four and eight; however, only two mirrors can also be used, if appropriate.

In addition to the reflective optical elements 3, 12 to 16, 21 to 26, the EUV lithography unit 1 also comprises non-optical components, which can be for example carrying structures for the reflective optical elements 3, 12 to 16, 21 to 26, sensors, actuators, etc. FIG. 1 represents, illustratively, a plurality of actuators 27 mounted on the rear side of the sixth mirror 26 of the projection lens 20 in order to carry out targeted deformation of this lens and, in the process, to compensate aberrations which occur when the structure is imaged onto the wafer W with the projection lens 20. For the targeted driving of the actuators 27, the EUV lithography unit 1 comprises a control device 28, in the form of a control computer, for example, which communicates via signal lines—not shown in the image—with the actuators 27.

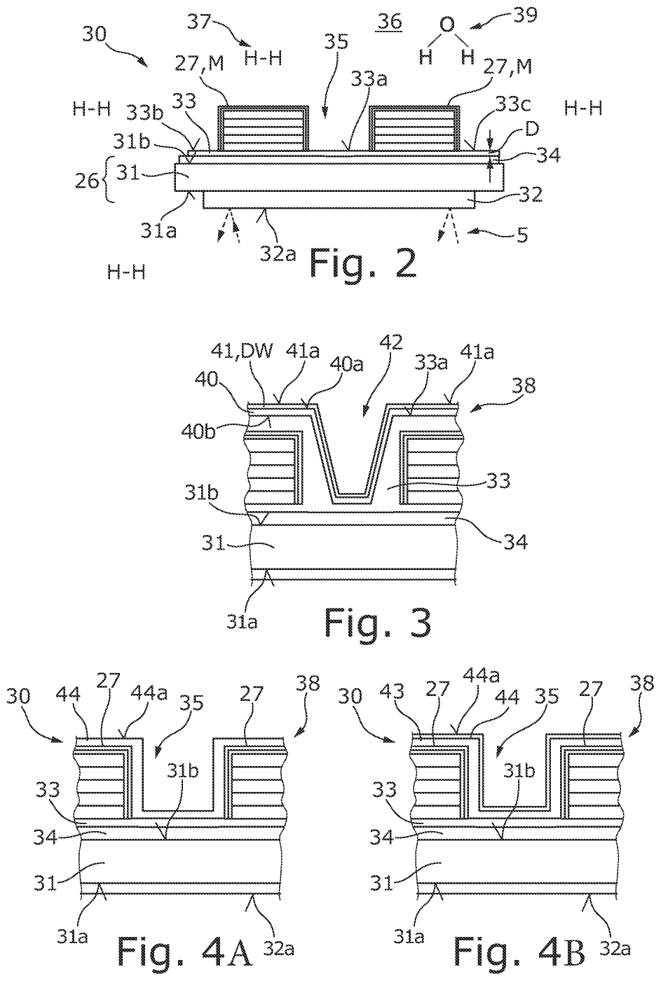

FIG. 2 shows the mirror 26 of FIG. 1 as part of a corresponding mirror arrangement 30 in a detailed representation. The mirror arrangement 30, more specifically the mirror 26, comprises a substrate 31, which in the example shown is formed of fused silica or titanium-doped fused silica (ULE). Different materials having a low thermal expansion coefficient, or a very low dependence of the thermal expansion coefficient on the temperature, examples being certain glass-ceramics, may likewise be used as substrate materials. Applied to a front side 31a of the substrate 31 of the mirror 26 is a reflective coating 32 configured such that incident EUV radiation 5 is reflected in a narrow spectral range around the operating wavelength of 13.5 nanometers for a specified range of incident angles, with a comparatively high reflectivity. The reflective coating 32 is configured such that it acts as an interference layer system for the EUV radiation 5 to be reflected. The reflective coating 32 comprises, in alternation, first layers of a first layer material in the form of silicon and second layers of a second layer material in the form of molybdenum. Different first and second layer materials, in the form of molybdenum and beryllium, for example, are likewise possible, depending on the operating wavelength.

Serving for targeted local deformation of a mirror face 32a formed on the reflective coating 32 are the actuators 27, which in the case of the example shown in FIG. 2 are configured as piezo actuators or electrostrictive actuators. The actuators 27 are secured with an adhesive layer 33 on the rear side 31b of the substrate 31. The adhesive layer 33 may be applied directly to the rear side 31b of the substrate 31, but in the example shown an interlayer 34 is applied to the rear side 31b of the substrate 31, and the adhesive layer 33 is applied to this interlayer 34. The material of the interlayer 34 may comprise, for example, Cr, V, Si, Al, Ta, Ti, Ru, Cu, Al₂O₃, Ta₂O₅, TiO₂, chromium oxide, vanadium oxide, La₂O₃, ZrO₂, etc.

In the example shown, the adhesive layer 33 has a constant thickness D and is applied over the area of the rear side 31b of the substrate 31. The actuators 27 are mounted or embedded onto the adhesive layer 33 and project over the adhesive layer 33. The actuators 27 are glued at a distance from one another in a two-dimensional grid on the rear side 31b of the substrate 31. For simplification of the representation, FIG. 2 shows only two, directly adjacent actuators 27, with an interspace 35 formed between them. It will be appreciated that in the grid in general there is a much larger number of actuators 27, with pairs of adjacent actuators 27 separated from one another by an interspace 35. The interspaces 35 between the actuators 27 generally have the same width; in other words, the actuators 27 are distributed evenly over the rear side 31b of the substrate 31. The actuators 27, or a plurality of actuators 27, may also form an assembly which has gaps or interspaces 35, or a plurality of actuator assemblies may be applied to the rear side 31a of the substrate 31. A single actuator or actuator assembly 27 may optionally be applied to the rear side 31b of the substrate 31.

The adhesive layer 33 extends not only under the actuators 27 or between the actuators 27 and the rear side 31b of the substrate 31, but also into a respective interspace 35 between two adjacent actuators 27. In the case of the example represented in FIG. 2, the thickness D of the adhesive layer 33 is selected such that the adhesive layer 33 does not project into the interspace 35, but instead finishes flush with the bottom side of the actuators 27 at surface regions 33a-c which are exposed to the surroundings. The thickness D of the adhesive layer 33 may alternatively be selected such that the interspace 35 is filled wholly or partly by the adhesive layer 33. The thickness D of the adhesive layer 33 may in particular also be selected to have a size such that the adhesive layer 33 covers the top side of the actuators 27. The adhesive layer 33 may also be thinner or have an irregular thickness.

The reflective optical elements 3, 12 to 16 of the illumination system 10 and the reflective optical elements 21 to 26 of the projection lens 20 of the EUV lithography unit 1 of FIG. 1 are arranged in a vacuum environment which has a residual gas atmosphere. In the surroundings 36 of the mirror arrangement 30 and hence also in the surroundings of the adhesive layer 33, at least during the cleaning cycles, there is hydrogen 37, which may be present in different excitation states, as for example in the form of molecular hydrogen (H₂), of excited molecular or atomic hydrogen, in the form of hydrogen ions, etc.

The components mounted on the rear side 31b of the substrate 31, especially the actuators 27, generally have hydrogen-sensitive material M, i.e. material which degrades on contact with the hydrogen 37, on their surface facing the surroundings 36. The hydrogen-sensitive material M may be, for example, the material of the housing of the actuators 27 and also may be conductor tracks, conductor cables, insulator layers applied to the actuators 27 and optionally to the interlayer 34, etc. Conductor tracks and insulator layers are generally produced from plastics materials which have a comparatively high solubility to hydrogen 37 and which degrade on chemical reaction with hydrogen. The material of the adhesive layer 33 and also, where appropriate, the material of the substrate 31 are also generally not chemically inert to the attack by hydrogen 37.

In order to protect the hydrogen-sensitive material M on the rear side 31a of the substrate 31 against the attack by hydrogen 37 from the surroundings 36 of the mirror arrangement 30, the mirror arrangement 30 has a hydrogen barrier 38, which may be configured in various ways, as described in more detail below with reference to FIG. 3 and to FIGS. 4A,B. FIG. 3 and FIGS. 4A,B each show only a detail of the mirror arrangement 30 or of the hydrogen barrier 38, respectively, though it generally extends over the entire rear side 31a of the substrate 31.

The hydrogen barrier 38 described in more detail below may also serve as a water vapor diffusion barrier for protecting the adhesive layer 33 against the penetration or the inward diffusion of water vapor 39 (cf. FIG. 2). The diffusion of water vapor 39 into the adhesive layer 33 or out of the adhesive layer 33 is a particular problem if the concentration of water vapor 39 in the surroundings 36 of the mirror arrangement 30 changes, since the expansion or contraction of the adhesive in the adhesive layer 33 is dependent on the amount of water vapor 39 absorbed, and leads to stresses in the adhesive layer 33 that are transferred to the substrate 31 and that may lead to unwanted deformations at the mirror face 32a. This is also the case for other organic materials connected mechanically to the mirror.

The hydrogen barrier 38 shown in FIG. 3 comprises a protective film 40 made of a flexible film material. Applied to the protective film 40, on its top side 40a facing away from the substrate 31, is a hydrogen barrier layer 41, which in the example shown consists of Al. Aluminum has a low hydrogen diffusion coefficient DW of less than around 5×10⁻¹⁴ m²/s. Aluminum, moreover, is a chemically inert material, which has a lower solubility for hydrogen 37 than the material of the adhesive layer 33.

Different materials as well, having on the one hand a low hydrogen diffusion coefficient DW of, for example, less than around 5×10⁻¹⁴ m²/s, preferably of less than 1×10⁻¹⁷ m²/s, in particular of less than 1×10⁻²¹ m²/s, may be applied as a hydrogen barrier layer 41 to the protective film 40, examples being Au, Ag, Zn, Mo, Si, W, Ti, Sn, Sb, Pt, Ni, Fe, Co, Cr, V, Cu, Mn, Pb, their oxides, borides, nitrides and carbides, C, B₄C, and compounds thereof. The hydrogen barrier layer 41 may also comprise at least one metal oxide or consist of a metal oxide. In particular, metal oxides which have a high (negative) free enthalpy of formation of less than around −300 kJ/mol O₂, preferably of less than −800 kJ/mol O₂, more preferably of less than −1000 kJ/mol O₂, are generally inert toward a chemical reaction with hydrogen 37. In particular Al₂O₃, MgO, CaO, La₂O₃, TiO₂, ZrO₂, Ta₂O₅, Y₂O₃, Ce₂O₃ and compounds thereof have proven advantageous materials for the hydrogen barrier layer 41. Nitrides as well, metal nitrides for example, which have a free enthalpy of formation of less than −200 kJ/mol N₂, preferably of less than −350 kJ/mol N₂, more preferably of less than −600 kJ/mol N₂, are generally inert toward a chemical reaction with hydrogen 37 and may therefore be used as materials for the hydrogen barrier layer 41.

In the case of the example shown in FIG. 3, the protective film 40 is adhered over the full area of the top side 33a of the adhesive layer 33. The adhesive layer 33 in this case projects upwardly over the top side of the actuators 27. Between pairs of adjacent actuators 27, the protective film 40 projects into the interspace 35, meaning that it extends from the top side of the two actuators 27 downward in the direction of the rear side 31a of the substrate 31. The protective film 40 covers a pot-shaped depression 42 in the adhesive layer 33, in the case of the example shown in FIG. 3. In the example shown in FIG. 3, the depression 42 extends in the interspace 35 until approximately the level of the bottom side of the actuators 27. The depression 42 reduces the volume of adhesive located within the interspace 35. This is advantageous in order to reduce stresses in the adhesive layer 33 when water vapor 39 is taken up/given off, and in this way to reduce stresses in the substrate 31.

In the case of the example shown in FIG. 3, the film 40 is not connected directly to the actuators 27, but is connected only to the surface 33a of the adhesive layer 33. The mutually opposing sides of the protective film 40 can therefore move toward one another or away from one another in the event of an adhesive drift, in the region of the pot-shaped or groove-shaped depression 42, in order to counteract the incidence of stresses in the adhesive layer 33.

In the example shown, the protective film 40 forms a water vapor diffusion barrier, meaning that it consists of or comprises a material which prevents or counteracts the penetration of water vapor 39 into the adhesive layer 33. For this purpose the protective film 40 is formed of a material of low water diffusivity or comprises a material having low water diffusivity. The protective film 40 may be a two-ply film, for example, having a first ply of Al₂O₃ as a material with low water diffusivity, which acts as a water vapor diffusion barrier and which is applied to a second ply, e.g., a self-adhesive ply. Alternatively or additionally, the protective film 40 may have a hydrophobic surface 40a, which may be generated, for example, by a plasma treatment or termination. The surface 41a of the water vapor barrier layer 41 (e.g., with Al as layer material) may also be rendered hydrophobic with suitable surface treatment. In the event that the water vapor diffusion barrier in the form of the protective film 40 is itself insensitive to hydrogen, it may be advantageous to switch the sequence, so that the hydrogen barrier layer 41 is applied on the bottom side 40b of the protective film 40 that faces the substrate 31. Also possible is the application of a respective hydrogen barrier layer 41 to the top side 40a and to the bottom side 40b of the protective film 40.

FIGS. 4A and 4B show a hydrogen barrier in the form of a coating 38 which is applied to the rear side 31b of the substrate 31 and to the components provided there, in other words, in particular, to the actuators 27 and to the adhesive layer 33. In the case of the example shown in FIG. 4A, the coating 38 consists of a single hydrogen barrier layer 44, which is applied not only to the top side of the actuators 27 but also, in the respective interspace 35, to the side walls of the actuators 27 and to the top side of the adhesive layer 33. In the example shown, the hydrogen barrier layer 44 is formed of Al₂O₃, but may also comprise one or more of the materials described earlier on above, or different materials, which first have a low hydrogen diffusion coefficient DW and secondly have a low solubility for hydrogen 37.

FIG. 4B shows a hydrogen barrier 38 in the form of a coating which likewise completely covers the hydrogen-sensitive material M on the rear side 31b of the substrate 31. In contrast to the coating 38 shown in FIG. 4A, the coating 38 shown in FIG. 4B has a comparatively thin hydrogen barrier layer 44, which is applied to a further, comparatively thick, covering layer 43. The layer 43 covering the hydrogen-sensitive material M has the function of compensating irregularities and providing better growth conditions for the hydrogen barrier layer 44. In the example shown, SiO₂ is present in the covering layer 43. The covering layer 43 typically has a thickness of more than 100 nm; the hydrogen barrier layer 44 typically has a thickness lower than 100 nm. In contrast to what is shown in FIG. 4B, the hydrogen barrier 38 may comprise a plurality of double layers each composed of a covering layer 43 and of a hydrogen barrier layer 44 applied thereto.

The hydrogen barrier layer 44 may be formed in particular of one or of two or more of the materials described earlier on above. The hydrogen barrier layer 44 may also comprise a hydrophobic material or its surface 44a may have hydrophobic properties so as to serve as a water vapor diffusion barrier.

In place of an individual hydrogen barrier layer 41, 44 as shown in FIG. 3 and in FIGS. 4A and 4B, the hydrogen barrier 38 may be configured as a coating having two or more hydrogen barrier layers applied one over another. In this way, for example, in the case of a double layer system, in other words of a coating 38 which comprises a pair of hydrogen barrier layers, the pinholes or defects in one individual layer are not continuous pinholes or defects in the following individual layer. In a coating 38 of this kind, therefore, different materials from among those already identified earlier on above are preferably applied in alternation, i.e. as a double layer. It is advantageous to apply two or more such double layers one over another. The materials of the hydrogen barrier layers may be, for example, alternately applied nitrides and carbides, in particular MAX phases, i.e., layered hexagonal nitrides and carbides. It will be appreciated that it is also possible for three or more of the above-stated materials to be used in a coating 38 in the form of a multilayer system.

The coating 38, in particular the hydrogen barrier layer 44, may be applied in various ways to the surface 33a of the adhesive layer 33 and to the actuators 27—for example, by deposition from the gas phase, i.e. by PVD, CVD, for example by plasma-enhanced CVD or PVD, by ALD, in particular by plasma-enhanced ALD, by sputtering, in particular by magnetron sputtering, by electron beam evaporation, etc. The operating parameters when applying the coating 38 or the hydrogen barrier layer 44 are typically selected such that it may be deposited with a high density and with as far as possible no pinholes.

The hydrogen barrier 38 shown in FIG. 3 may be combined, optionally, with the hydrogen barrier 38 shown in FIG. 4A or 4B by covering a section or a subregion on the rear side 31a of the substrate 31 with a hydrogen barrier 38 in the form of the protective film 40 (coated with the hydrogen barrier layer 41), and covering a further section or subregion on the rear side 31b of the substrate 31 with a hydrogen barrier 38 in the form of a coating in accordance with FIG. 4A or 4B. In the event that materials which are not hydrogen-sensitive are mounted on the rear side 31b of the substrate 31, it is also possible optionally to dispense with the provision of the hydrogen barrier 38 on the rear side 31b of the substrate 31 in those regions in which these materials are provided.

What is claimed is:

1. A mirror arrangement comprising:
a substrate, which has a front side having a mirror face for reflecting radiation, and a rear side facing away from the front side,
at least one actuator for generating deformations of the mirror face,
wherein the at least one actuator is secured with an adhesive layer on the rear side of the substrate, and
a hydrogen barrier which is configured to protect a hydrogen-sensitive material on the rear side of the substrate from hydrogen damage from hydrogen surrounding the mirror arrangement.

2. The mirror arrangement as claimed in claim 1, wherein exposed surface regions of the adhesive layer are protected by the hydrogen barrier from the damage from the hydrogen.

3. The mirror arrangement as claimed in claim 2, wherein the hydrogen barrier forms a water vapor diffusion barrier protecting the adhesive layer from water vapor.

4. The mirror arrangement as claimed in claim 1, wherein a surface of the hydrogen barrier that faces the surrounding hydrogen is hydrophobic and/or wherein the hydrogen barrier comprises at least one hydrophobic material.

5. The mirror arrangement as claimed in claim 1, wherein the hydrogen barrier has a hydrogen diffusion coefficient of less than 5×10⁻¹⁴ m²/s.

6. The mirror arrangement as claimed in claim 1, wherein the hydrogen barrier comprises at least one material and/or a material combination which has a lower solubility for hydrogen than does the hydrogen-sensitive material.

7. The mirror arrangement as claimed in claim 1, wherein the hydrogen barrier comprises at least one oxygen-containing chemical compound material having a free enthalpy of formation of less than −400 kJ/mol O₂.

8. The mirror arrangement as claimed in claim 1, wherein the hydrogen barrier comprises at least one nitrogen-containing chemical compound material having a free enthalpy of formation of less than −200 kJ/mol N₂.

9. The mirror arrangement as claimed in claim 1, wherein the hydrogen barrier comprises at least one metal oxide which is preferably selected from the group consisting essentially of: Al₂O₃, MgO, CaO, La₂O₃, TiO₂, ZrO₂, Ta₂O₅, Y₂O₃, Ce₂O₃, and compounds thereof.

10. The mirror arrangement as claimed in claim 9, wherein the at least one metal oxide is selected from the group consisting essentially of: Al₂O₃, MgO, CaO, La₂O₃, TiO₂, ZrO₂, Ta₂O₅, Y₂O₃, Ce₂O₃, and compounds thereof.

11. The mirror arrangement as claimed in claim 1, wherein the hydrogen barrier comprises at least one material selected from the group consisting essentially of: Al, Au, Ag, Zn, Mo, Si, W, Ti, Sn, Sb, Pt, Ni, Fe, Co, Cr, V, Cu, Mn, Pb, their oxides, borides, nitrides and carbides, and also C and B₄C.

12. The mirror arrangement as claimed in claim 1, wherein the hydrogen barrier has a coating or forms a coating which covers the hydrogen-sensitive material at least partly.

13. The mirror arrangement as claimed in claim 11, wherein the coating comprises at least one hydrogen barrier layer.

14. The mirror arrangement as claimed in claim 13, wherein the at least one hydrogen barrier layer is applied on a further layer.

15. The mirror arrangement as claimed in claim 1, wherein the hydrogen barrier has a protective film or forms a protective film which covers the hydrogen-sensitive material at least partly.

16. The mirror arrangement as claimed in claim 15, wherein the protective film has a surface comprising at least one hydrogen barrier layer.

17. The mirror arrangement as claimed in claim 15, wherein the protective film projects into an interspace between adjacent actuators and covers a depression in the adhesive layer.

18. The mirror arrangement as claimed in claim 1, wherein the actuators are configured as piezo actuators or as electrostrictive actuators.

19. An optical arrangement in a lithography apparatus, comprising: at least one mirror arrangement as claimed in claim 1.
